(19) United States
(12) Patent Application Publication
(10) Pub. No.: US 2026/0110579 A1
(43) Pub. Date: Apr. 23, 2026

(54) SENSOR ELEMENT WITH OVERVOLTAGE PROTECTION

(71) Applicant: Innovative Sensor Technology IST AG, Ebnat-Kappel (CH)

(72) Inventors: Ling Sieben-Xu, Neu St. Johann (CH); Yannick Barb, Ebnat-Kappel (CH); Livia Schneider, Wattwil (CH); Melanie Müller, Wattwil (CH); Julia Schläpfer, Ebnat-Kappel (CH)

(21) Appl. No.: 19/360,722

(22) Filed: Oct. 16, 2025

(30) Foreign Application Priority Data
Oct. 21, 2024 (DE) 10 2024 130 465.0

(51) Int. Cl. G01K 1/08; G01K 1/14; G01K 7/18; H05K 9/00

(52) U.S. Cl. CPC G01K 1/08; G01K 1/14; G01K 7/18; H05K 9/0067

(57) ABSTRACT

A sensor element comprises a carrier element; a sensor structure applied to the carrier element for detecting a measured variable, wherein the sensor structure has first and second electrical contact points and is operable by applying a voltage between the first and second electrical contact points; and an overvoltage protection element applied to the carrier element and comprising a first conductor track and a first pad and a second conductor track and a second pad spaced apart from the first pad. The first conductor track electrically connects the first electrical contact point to the first pad and the second electrical conductor track connects the second electrical contact point to the second pad. The first pad and the second pad are arranged at a distance from each other on the carrier element forming a spark gap between the first pad and the second pad.

### CROSS-REFERENCE TO RELATED APPLICATION

The present application is related to and claims the priority benefit of foreign patent application no. DE 10 2024 130 465.0, filed on Oct. 21, 2024, the entire contents of which are incorporated herein by reference.

### TECHNICAL FIELD

The present disclosure relates to a sensor element.

### BACKGROUND

Many sensor elements for determining physical, chemical, and/or biological measured variables of a measuring medium or the environment are known from the prior art.

For example, temperature sensors are known for measuring the temperature of a measuring medium. They are manufactured using thin-film or thick-film technology, for example, and have a functional layer, e.g., made of platinum, on a substrate. This functional layer can be used to determine the temperature of a medium with which the functional layer is in thermal interaction. The measuring medium is in particular a gaseous or liquid fluid.

Another example is thermal flow sensors, which typically consist of one or more temperature sensors and at least one heating element.

Further examples of sensor elements are humidity sensors, strain sensors, gas sensors, light sensors, etc. The part of the sensor element that is functional for detecting the measured variables is referred to below as the sensor structure. In addition to the sensor structure, a sensor element comprises, among other things, a carrier element or substrate, conductor tracks, contact pads and, if necessary, electronic components and/or circuits.

All of these sensor elements are sensitive to electrostatic discharge (ESD). These manifest themselves in voltage breakdowns due to high potential differences. These voltage breakdowns briefly produce high electrical currents, which can irreversibly damage the components of the sensor elements, especially the sensor structures.

### SUMMARY

Proceeding from this problem, the present disclosure is based on the object of presenting a sensor element with integrated protection against damage caused by electrostatic discharge.

The object is achieved by a sensor element, the sensor element comprising:
a carrier element;
a sensor structure applied or attached to the carrier element for detecting a physical, chemical, and/or biological measured variable, wherein the sensor structure has a first electrical contact point and a second electrical contact point, wherein the sensor structure is operable by applying a voltage between the first electrical contact point and the second contact point electrical contact point; and
an overvoltage protection element applied to the carrier element and comprising a pair of sub-elements, consisting of a first sub-element and a second sub-element, wherein the first sub-element comprises a first conductor track and a first pad, wherein the second sub-element comprises a second conductor track and a second pad spaced apart from the first pad, wherein the first conductor track electrically connects the first electrical contact point to the first pad, wherein the second electrical conductor track connects the second electrical contact point to the second pad, wherein the first pad and the second pad are designed and arranged at a first distance from each other on the carrier element such that a spark gap is formed between the first pad and the second pad.

The sensor element according to the present disclosure has an integrated structure in the form of an overvoltage element which is connected in parallel to the sensor structure. The overvoltage element essentially consists of a spark gap formed between two pads. This provides reliable ESD protection.

Instead of a voltage, a current or power can be applied to operate the sensor structure.

One embodiment of the sensor element provides that the first pad and the second pad are arranged such that, when a voltage that exceeds a first threshold value is present between the first contact point and the second contact point, electrical current is discharged parallel to the sensor structure via the overvoltage protection element. It is provided that the threshold value is multiple kV. Below the threshold value, the applied (operating) voltage generates a desired current, by means of which the sensor element is operated and which is required to ascertain the measured variable. Electrostatic discharges cause short-term voltages that are many times higher than the typical operating voltages (which are, for example, 5 V). If a voltage higher than the threshold value is present, the air gap between the pads of the overvoltage protector is ionized so that the high discharge current is discharged via this ionized air gap and thus does not damage the sensor structure connected in parallel.

The magnitude of the threshold value is defined in particular via the length of the spark gap, i.e., the distance between the second pad and the first pad. Generally speaking, a longer length defines a higher threshold.

In accordance with a development of the sensor element, it is provided that the overvoltage protection element has one or more further pairs of sub-elements, each comprising a further first sub-element, each with a further first pad and a further first conductor track, and a further second sub-element, each with a further second pad and a further second conductor track, wherein the further first electrical conductor tracks in each case connect the second electrical contact point to the corresponding further first pad, wherein the further second electrical conductor tracks in each case connect the second electrical contact point to the corresponding further second pad, wherein the further first pads and the further second pads are designed and in each case arranged at a further distance from each other on the carrier element such that a further spark gap is formed in each case between the corresponding first further pad and the corresponding further second pad.

In this case, it can be provided that, in the case that multiple further pairs of sub-elements are provided, the further distances to each other and to the first distance are different.

The further distance, or the further distances, in each case define further threshold values for the applied voltage.

In this way, multiple levels of protection can be provided, which act against different overvoltage levels.

An advantageous embodiment of the sensor element provides that the first pad and the second pad together with the distance therebetween and/or the further first pad and the further second pad, or the further first pads and the further second pads, together with the corresponding further distances, are covered by a layer of a dielectric material. Using this material, the threshold value can be influenced or adjusted. For example, covering the air gap with glass creates a higher threshold. Conversely, by covering the air gap while maintaining the same threshold value, the required distance between the pads can be influenced.

In accordance with a first variant, it is provided that the carrier element is a substrate made of a metallic material, ceramic material, or semiconductor material, which substrate is in particular planar. The sensor structure can be applied to the carrier element by means of a thick-film or thin-film process.

PVD or CVD processes are suitable as thin-film processes. The material of the sensor structure is in particular a metal, for example platinum in the case of a temperature sensor. A suitable thick-film process, for example, is a screen printing process, in which the material for the sensor structure is initially in paste form and comprises a metal or a conductive ceramic. After printing, the sensor structure must be thermally treated, for example heated, to remove the liquid components of the paste.

According to a second variant, it is provided that the carrier element is a printed circuit board. The sensor structure can then be an electronic component, in particular an SMD or THT component.

An advantageous embodiment of the sensor element provides that the overvoltage protection element is applied to the carrier element by means of a thick-film or thin-film process. In the case that the sensor structure is also applied by means of a thick-film or thin-film process, the sensor structure and the overvoltage protection element can be manufactured in a single process step.

In accordance with one embodiment of the sensor element, it is provided that the overvoltage protection element and the sensor structure are applied or attached to a common side of the carrier element. Alternatively, it may be provided that the overvoltage protection element and the sensor structure are applied or attached on different sides of the carrier element.

### BRIEF DESCRIPTION OF THE DRAWINGS

The present disclosure is explained in greater detail with reference to the following figures, in which:

FIG. 1 shows a first embodiment of the sensor element according to the present disclosure;

FIG. 2 shows a second embodiment of the sensor element according to the present disclosure;

FIG. 3 shows a third embodiment of the sensor element according to the present disclosure;

FIG. 4 shows a fourth embodiment of the sensor element according to the present disclosure; and

FIG. 5 shows a fifth embodiment of the sensor element according to the present disclosure.

### DETAILED DESCRIPTION

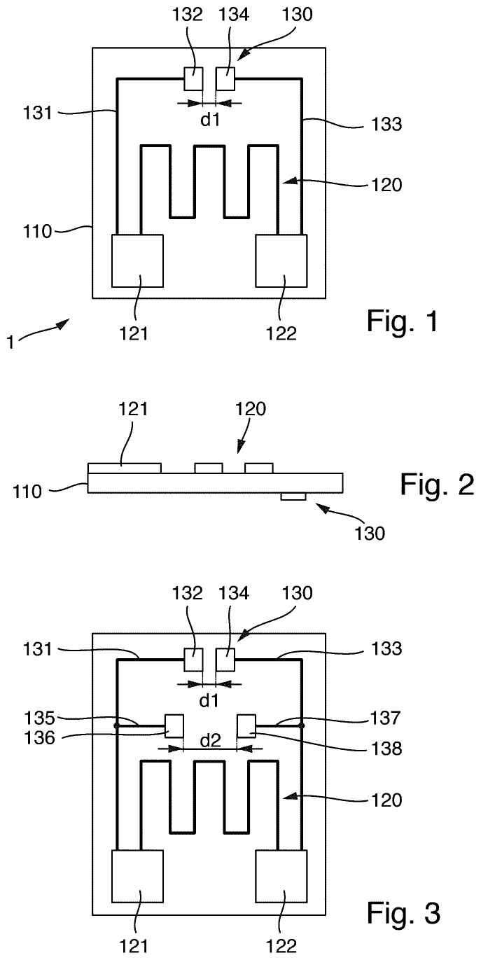

FIG. 1 shows a first exemplary embodiment of the sensor element 1 according to the present disclosure in a plan view of the sensor element 1. The sensor element 1 consists of a carrier element 110 in the form of a planar substrate. The substrate, for example, is made of a ceramic material.

A sensor structure 120 with a first electrical contact point 121 in the form of a contact pad and a second electrical contact point 122 in the form of a contact pad is applied to the carrier element 110. The sensor structure 120 with the two contact points 121, 122 consists of a metallic material, in particular platinum, and in the present case is applied to the carrier element 110 by means of a sputtering or screen printing process.

The sensor structure 120 is used to detect a temperature. For this purpose, the sensor structure 120 has a meander-shaped portion with a thin cross section. By applying an electrical voltage or a current between the two contact points 121, 122, the electrical resistance of the meander-shaped portion can be detected. Since this is temperature-dependent, the temperature of the environment or a medium can be determined.

In this and the following embodiments, a temperature sensor is described. However, other types of sensor structures can also be used, as long as they can be supplied with electrical voltage by means of two or more contact points 121, 122. It may also be provided to provide an electronic component, for example a diode or a transistor, as the sensor structure 120.

To protect the sensitive sensor structure 120 from electrostatic discharges, an overvoltage protection element 130 is applied to the carrier element 110. The overvoltage protection element 130 consists of a first sub-element with a first pad 132 and a first electrical conductor track 131 connecting the first pad 132 to the first contact point 121, as well as a second sub-element with a second pad 134 and a second electrical conductor track 133 connecting the second pad 134 to the second contact point 122.

The overvoltage protection element 130 can consist of the same material as the sensor structure 120 and can be applied to the carrier substrate 110 in the same process step by means of the same process.

The first sub-element and the second sub-element are arranged such that the two pads 132, 134 have a first distance d1 from each other, i.e., the two pads 132, 134 do not touch each other. This creates a so-called spark gap between the two pads 132, 134. This means that when a low electrical voltage is applied, no current flows from the first contact point 121 to the second contact point 122. Only when a first threshold value is exceeded does a flashover occur from the first pad 132 to the second pad, whereby electrical current is discharged parallel to the meander structure via the overvoltage protection element 130.

Table 1, see below, shows possible dimensions and example threshold values. In this case, the first distance between the pads 132, 134 is 200 μm. The first threshold is therefore 4 kV.

In this way, a simple and reliable protector against overvoltages is created for the sensor element 1 and can be integrated directly with the sensor structure 120 on a common carrier element 110.

FIG. 2 shows a second embodiment of the sensor element 1 as a cross section. The dimensions of the elements of the sensor element 1 basically correspond to those of the sensor element of the exemplary embodiment shown in FIG. 1. However, the overvoltage protection element 130 here is not applied to the same side of the carrier element 110, but is located on the side of the substrate 110 opposite the sensor structure 120. The conductor tracks 131, 133 here contact the corresponding contact points 121, 122 by means of through-holes through the carrier element 110.

FIG. 3 shows a third exemplary embodiment of the sensor element 1 as a plan view. The dimensions of the elements of the sensor element 1 basically correspond to those of the sensor element of the exemplary embodiment shown in FIG. 1. However, the overvoltage protection element 130 is extended in this exemplary embodiment: In addition to the first and second sub-elements, two further sub-elements are present. A third pad 136 and a fourth pad 138 are thus provided, which are each connected to the corresponding contact points 121, 122 by means of further conductor tracks 135, 137. In this case, the first conductor track 131 and the further first conductor track 135 can be combined at least in portions, and the second conductor track 131 and the further second conductor track 137 can be combined at least in portions.

The further first pad 136 has a second distance d2 from the further second pad 138. This provides an additional threshold for the overvoltage. Table 1, see below, shows possible dimensions and example threshold values. In this case, the first distance d1 between pads 132, 134 is 200 μm. The first threshold is therefore 4 kV. The further distance d2 between the pads 136, 138 is 300 μm. The further threshold value is therefore 8 kV.

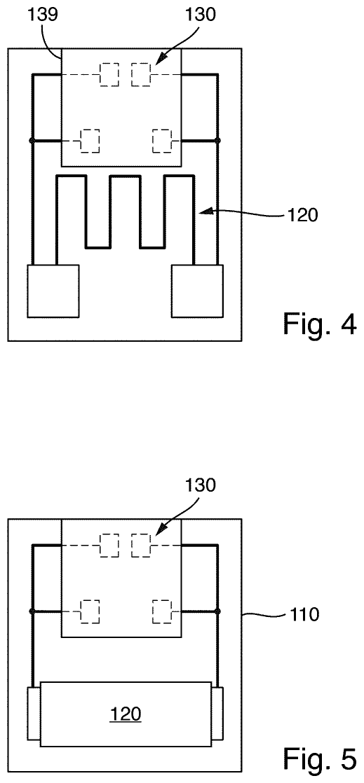

FIG. 4 shows a fourth exemplary embodiment of the sensor element 1 as a plan view. The dimensions of the elements of the sensor element 1 basically correspond to those of the sensor element of the exemplary embodiment shown in FIG. 2. A layer 139 is additionally shown, which is applied over the pads 132, 134, 136, 138 and the relevant spark gaps formed between the pads 132, 134, 136, 138. The layer 139 consists of a dielectric material and is applied by means of a thick-film or thin-film process.

The dielectric material influences the respective threshold value of the spark gap. By choosing the material, the threshold value can be precisely selected. Accordingly, the distance between pads 132, 134, 136, 138 can be influenced while keeping the threshold value constant.

In this example, glass is chosen as the dielectric material. Table 1, see below, shows possible dimensions and example threshold values for this case. In this case, the first distance d1 between pads 132, 134 is 5 μm. The first threshold is 3 kV, since there is a layer 139 of glass. The further distance d2 between the pads 136, 138 is 10 μm. The further threshold value is 4 kV, since there is a layer 139 of glass.

FIG. 4 shows a fourth exemplary embodiment of the sensor element 1 as a plan view. The dimensions of the elements of the sensor element 1 basically correspond to those of the sensor element of the exemplary embodiment shown in FIG. 2. The substrate is replaced here by a printed circuit board as a carrier element 110. The sensor structure 120 is designed here as an electronic component (temperature sensor with housing), which is soldered to the contact points 121, 122. The overvoltage protection element 130 is applied as described in the previous examples. The distances d1, d2 and threshold values correspond to those of the embodiment shown in FIG. 4.

TABLE 1

| | | |
|---|---|---|
| Distance (d1, d2) | Dielectric material | Threshold |

| | | | |
|---|---|---|---|
| 5 | μm | Glass | 3 kV |
| 10 | μm | Glass | 4 kV |
| 300 | μm | n.a. (air) | 8 kV |
| 200 | μm | n.a. (air) | 4 kV |

1. A sensor element comprising:
a carrier element;
a sensor structure applied or attached to the carrier element for detecting a physical, chemical, and/or biological measured variable, wherein the sensor structure has a first electrical contact point and a second electrical contact point, wherein the sensor structure is operable by applying a voltage between the first electrical contact point and the second electrical contact point; and
an overvoltage protection element applied to the carrier element and including a first conductor track and a first pad and a second conductor track and a second pad spaced apart from the first pad, wherein the first conductor track electrically connects the first electrical contact point to the first pad, wherein the second electrical conductor track connects the second electrical contact point to the second pad, and wherein the first pad and the second pad are designed and arranged at a first distance from each other on the carrier element to form a spark gap between the first pad and the second pad.

2. The sensor element according to claim 1, wherein the first pad and the second pad are arranged such that, when a voltage that exceeds a first threshold value is present between the first contact point and the second contact point, electrical current is discharged parallel to the sensor structure via the overvoltage protection element.

3. The sensor element according to claim 1, wherein the overvoltage protection element further includes a further first pad and a further first electrical conductor track and a further second pad and a further second electrical conductor track, wherein the further first electrical conductor track connects the first electrical contact point to the corresponding further first pad, wherein the further second electrical conductor track connects the second electrical contact point to the corresponding further second pad, wherein the further first pad and the further second pad are designed and in each case arranged at a further distance from each other on the carrier element such that a further spark gap is formed between the corresponding first further pad and the corresponding further second pad.

4. The sensor element according to claim 3, wherein, in the case that multiple further pairs of pads and electrical conductor tracks are provided, the further distances to each other and to the first distance are different.

5. The sensor element according to claim 4, wherein the further distance or the further distances each define further threshold values for the applied voltage.

6. The sensor element according to claim 3, wherein the first pad and the second pad together with the distance therebetween and/or the further first pad and the further second pad together with the corresponding further distances, are covered by a layer of a dielectric material.

7. The sensor element according to claim 1, wherein the carrier element is a planar substrate made of a metallic material, a ceramic material, or a semiconductor material.

8. The sensor element according to claim 7, wherein the sensor structure is applied to the carrier element via a thick-film or thin-film process.

9. The sensor element according to claim 1, wherein the carrier element is a printed circuit board.

10. The sensor element according to claim 9, wherein the sensor structure is an electronic component, including a surface mount device (SMD) or a through-the-hold (THT) component.

11. The sensor element according to claim 1, wherein the overvoltage protection element is applied to the carrier element via a thick-film or thin-film process.

12. The sensor element according to claim 1, wherein the overvoltage protection element and the sensor structure are applied or attached to a common side of the carrier element.

13. The sensor element according to claim 1, wherein the overvoltage protection element and the sensor structure are applied or attached to different sides of the carrier element.
